(19) United States
(12) Patent Application Publication
(10) Pub. No.: US 2014/0225646 A1
(43) Pub. Date: Aug. 14, 2014

(54) DECODER CIRCUITS HAVING METAL-INSULATOR-METAL THRESHOLD SWITCHES

(71) Applicants: Matthew D. Pickett, San Francisco, CA (US); Gilberto Medeiros Hibeiro, Palo Alto, CA (US)

(72) Inventors: Matthew D. Pickett, San Francisco, CA (US); Gilberto Medeiros Hibeiro, Palo Alto, CA (US)

(21) Appl. No.: 14/346,554

(22) PCT Filed: Nov. 4, 2011
(86) PCT No.: PCT/US2011/059341

§ 371 Date: Mar. 21, 2014

(51) Int. Cl. G11C 8/10

(52) U.S. Cl. CPC G11C 8/10
USPC 326/105

(57) ABSTRACT

Decoder circuits having negative differential resistance (NDR) devices are described. In an example, a decoder circuit includes a plurality of input lines to receive select signals, a bias logic to provide a voltage bias, a plurality of output lines to provide output signals, and a plurality of metal-insulator-metal (MIM) threshold switches coupled to the plurality of input lines, the bias logic, and the plurality of output lines. Each of the plurality of MIM threshold switches operating as either a current-controlled positive or negative resistance to map an input logic state of the select signals to an output logic state of the output signals.

### BACKGROUND

Decoders and de-multiplexers have a wide range of applications in digital circuits, including communications routing, memory addressing, and computation. Decoders and de-multiplexers can be fabricated as complementary metal oxide semiconductor (CMOS) logic circuits on an integrated circuit (IC). In some applications, however, it is desirable to fabricate a decoder circuit without using crystalline silicon for CMOS devices. Decoding schemes have been proposed that do not require CMOS devices, such as nanowire field effect transistor (FET) logic, resistor logic, or diode logic. Loading effects (e.g., voltage drops) inherent in resistor and diode logic, however, minimizes the selection margins (e.g., the difference between “on” and “off”) to a point where such logic is impractical for several realistic decoder applications, such as memory addressing. Further, nanowire approaches require bottom-up assembly during fabrication, which can be impractical given current semiconductor manufacturing techniques for producing ICs.

### BRIEF DESCRIPTION OF THE DRAWINGS

Some embodiments of the invention are described with respect to the following figures:

FIG. 1 is a schematic diagram showing a decoder circuit according to an example implementation;

FIG. 2 shows a graph relating current through a NDR switch to voltage across the NDR switch according to an example implementation;

FIG. 3 is a block diagram showing a memory controller circuit according to an example implementation;

FIG. 4 is a diagram showing an integrated circuit (IC) device according to an example implementation; and

FIG. 5 shows a cross-section of an MIM threshold switch according to an example implementation.

### DETAILED DESCRIPTION

Decoder circuits having negative differential resistance (NDR) devices are described. In an embodiment, a decoder circuit includes a plurality of input lines, bias logic, a plurality of output lines, and a plurality of metal-insulator-metal (MIM) threshold switches. The input lines receive select signals. The bias logic provides a voltage bias. The output lines provide output signals. The MIM threshold switches are coupled to the input lines, the bias logic, and the output lines. Each of the MIM threshold switches operates as either a current-controlled positive or negative resistance to map an input logic state of the select signals to an output logic state of the output signals. In an example, two of such decoder circuits can be used to provide row selection and column selection signals, respectively, for an array of memory cells. In an example, the decoder circuit can be formed on a thin-film integrated circuit (IC), where each of the MIM threshold switches is formed using a metal film, an insulator film, and another metal film. In an example, a decoder circuit having MIM threshold switches can be formed as a thin film on top of an IC die. For example, a thin film decoder circuit with MIM threshold switches can be formed over a memory IC die to provide the functionality of a memory controller.

Several technologies have been proposed for decoding applications, but each has distinct limitations. Complementary metal oxide semiconductor (CMOS)-based devices provide reliable decoder circuits using CMOS devices, such as field effect transistors (FETs), but such devices are formed in crystalline silicon. Consequently, CMOS-based decoders can occupy substantial silicon area in a memory IC. Resistor/diode logic can be formed on substrates other than crystalline silicon, but the resistor/diode devices have larger voltage drops that consume most of the margin for selecting the devices (e.g., the voltage difference between “on” and “off”). Resistor/diode logic is thus not a practical solution for larger decoder circuits, such as those required for large memory arrays. Nanowire FET logic requires a bottom-up process, which precludes reliable fabrication of ICs. The decoder circuits in embodiments described herein include MIM devices that can be selected/unselected to provide the digital logic of the decoder. The MIM threshold switch-based device provides manageable voltage margins and is substrate agnostic. In examples, the MIM threshold switch-based decoder devices can be formed using thin-film processes. The current-controlled negative resistance characteristic of the MIM devices enables reasonable margins in contrast to resistor/diode-based devices. Embodiments of decoder circuits can be understood with respect to the following example implementations.

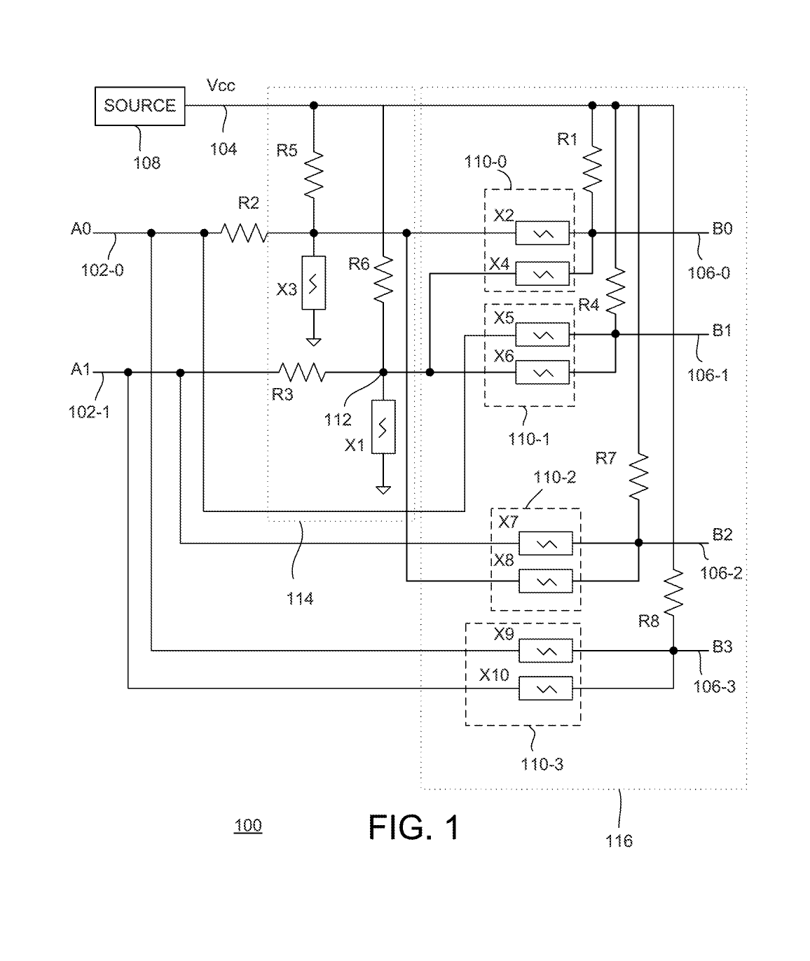

FIG. 1 is a schematic diagram showing a decoder circuit 100 according to an example implementation. The decoder circuit 100 includes input lines 102-0 and 102-1 (collectively input lines 102), a bias line 104, a plurality of resistors designated R1 through R8, a plurality of switches designated X1 through X10, and output lines 106-0 through 106-3 (collectively output lines 106). The bias line 104 can be coupled to a voltage source 108 to provide a voltage Vcc for biasing the decoder circuit 100. The input lines 102-0 and 102-1 receive digital signals A0 and A1, respectively. The digital signals A0 and A1 can have a voltage of Vcc or a reference voltage. For purposes of clarity by example, the reference voltage is assumed to be electrical ground (0 volts). Assume the margin between Vcc and the reference voltage denotes a difference between logical low (0) and logical high (1). The signals A0 and A1 represent a two-bit input symbol. The decoder circuit 100 produces output signals B0 through B3 in response to the input signals A0 and A1. The signals B0 through B3 represent a four-bit output symbol. In the present example, the relationship between an input symbol A1A0 and an output symbol B3B2B1B0 is as follows, where “0” denotes logic low or reference voltage, and “1” denotes logic high or Vcc:

| A1A0 | B3B2B1B0 |
|---|---|
| 00 | 0001 |
| 01 | 0010 |
| 10 | 0100 |
| 11 | 1000 |

The plurality of resistors R1 through R8 implement bias logic to provide a voltage bias to the switches X1 through X10. Each of the resistors R1 through R8 and the switches X1 through X10 are two-terminal devices. The structure of the decoder circuit 100 can be described as follows. The resistor R1 is coupled between the bias line 104 and first terminals of the switches X2 and X4, respectively. The resistor R2 is coupled between the input line 102-0 and a first terminal of the switch X3. The resistor R3 is coupled between the input line 102-1 and a first terminal of the switch X1. The resistor R4 is coupled between the bias line 104 and first terminals of the switches X5 and X6. The resistor R5 is coupled between the bias line 104 and the first terminal of the switch X3. The resistor R6 is coupled between the bias line 104 and the first terminal of the switch X1. The resistor R7 is coupled between the bias line 104 and first terminals of the switches X7 and X8, respectively. The resistor R8 is coupled between the bias line 104 and first terminals of the switches X9 and X10, respectively. Second terminals of the switches X1 and X3 are respectively coupled to the reference voltage (e.g., ground). A second terminal of the switch X2 is coupled to the first terminal of the switch X3. A second terminal of the switch X4 is coupled to the first terminal of the switch X1. A second terminal of the switch X5 is coupled to the input line 102-0. A second terminal of the switch X6 is coupled to the first terminal of the switch X1. A second terminal of the switch X7 is coupled to the input line 102-1. A second terminal of the switch X8 is coupled to the first terminal of the switch X3. A second terminal of the switch X9 is coupled to the input line 102-0. A second terminal of the switch X10 is coupled to the input line 102-1.

In an example, each of the switches X1 through X10 functions as current-controlled negative differential resistance (NDR) devices (“NDR switches”). In an example, the switches X1 through X10 comprise metal-insulator-metal (MIM) switches that function as threshold switches, such as metal-oxide-metal structures formed on a substrate. Each of the switches X1 through X10 has a threshold voltage. When the voltage across a switch reaches the threshold voltage, the switch effectively provides a negative resistance. A device that exhibits a “negative resistance” will experience a decrease in voltage with a rise in current at certain current levels. This is opposed to standard electric devices that always experience an increase in voltage with an increase in current. Due to the negative resistance, each of the switches X1 through X10 will experience a decrease in voltage with the rising current.

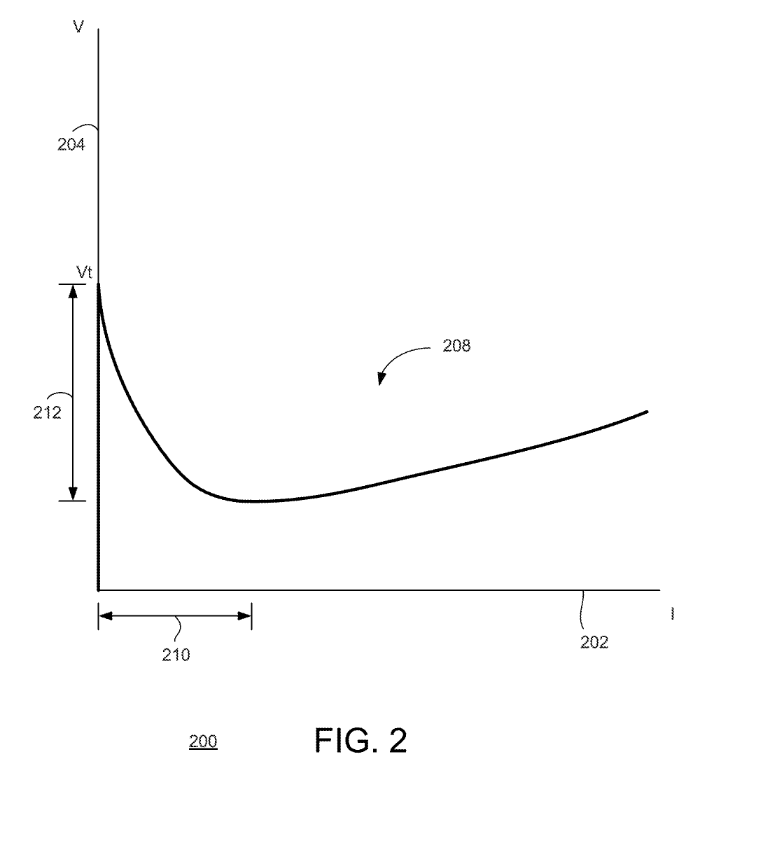

FIG. 2 shows a graph 200 relating current through a NDR switch to voltage across the NDR switch according to an example implementation. The graph 200 includes an axis 202 representing current (I), and an axis 204 representing voltage (V). A curve 208 represents the voltage-current relationship for the NDR switch. Ideally, no current flows through the NDR switch until the voltage across the NDR switch reaches the threshold voltage Vt (in a practical device conducts a small current relative to the current after the threshold voltage Vt is reached). Thus, prior to the threshold voltage Vt, the NDR switch provides high resistance. After the threshold voltage Vt is reached, the NDR switch conducts current. As the current increases, the voltage across the NDR switch decreases. There exists a region 210 of current where the voltage decreases with increasing current. Outside of the current region 210, the voltage will again begin to increase with increasing current. The current region 210 has a corresponding voltage region 212 across the NDR switch representing the voltage drop (Vdrop) across the switch. Thus, within the current region 210, the NDR switch provides low resistance.

Returning to FIG. 1, the decoder circuit 100 logically functions as follows. A pair 110-0 of the switches X2 and X4, a pair 110-1 of the switches X5 and X6, a pair 110-2 of the switches X7 and X8, and a pair 110-3 of the switches X9 and X10 each implement a logical AND gate having two inputs and one output. The outputs of the switch pairs 110-0 through 110-3 (collectively switch pairs 110) are respectively coupled to the output lines 106-0 through 106-3. The switches X1 and X3 each implement a logical inverter of the signals A1 and A0, respectively. The switch pair 110-0 receives logically inverted signals A0 and A1. The switch pair 110-1 receives signal A0 and logically inverted signal A1. The switch pair 110-2 receives logically inverted signal A0 and signal A1. The switch pair 110-3 receives signals A0 and A1. This logical configuration gives rise to the table of inputs and outputs described above.

The switch X1 provides logical inversion of the signal A1 as follows. The resistors R6 and R3 operate as a voltage divider a node 112, the output of which drives the switch X1. When the signal A1 is logical low (reference voltage), then voltage node 112 will be a fraction of Vcc determined by the values of the resistors R6 and R3 (referred to as Vdiv). For example, if resistors R6 and R3 are the same, than Vdiv will be Vcc/2. Assume the threshold voltage of the switch X1 is above Vdiv and the reference voltage is ground (0 volts). If the signal A1 is logical low, the switch X1 provide high resistance (conducting small current) and the voltage at node 112 will effectively remain at Vdiv. Thus, the signal A1 having the reference voltage is turned into a signal having the voltage Vdiv. If the signal A1 is logical high, the voltage at node 112 will move towards Vcc until reaching the threshold voltage of the switch X1, after which the switch X1 will conduct current (provide low resistance). As the switch X1 conducts current, the switch X1 will pull the voltage at node 112 towards the reference voltage to a voltage Vmin (e.g., in this example, Vmin is equal to the drop across the switch X1, Vdrop). By adjusting the values of R3 and R6, and the threshold voltage of X1, the margin between Vdiv and Vmin can provide detectable difference between logic high and logic low. The resistors R2 and R5, and the switch X3, operate similarly with respect to the signal A0. The switches X1 and X3 represent a first stage 114 of the decoder circuit 100 to logically invert the input signals A0 and A1.

The switches X2 and X4 provide a logical AND of inverted signals A0 and A1. Assume signals A0 and A1 are both logical low. As noted above, the logic low of the signals A0 and A1 will transition to Vdiv. The voltage across the switches X2 and X4 will reach Vcc−Vdiv. If the threshold voltage of the switches X2 and X4 is greater than Vcc−Vdiv, then the switches X2 and X4 will provide high resistance and conduct a small current. Thus, the voltage on the output line 106-1 will be near Vcc. If either or both of the signals A0 or A1 are logical high, then the voltage across one or both of the switches X2 and X4 will approach Vcc−Vmin. Assuming the threshold voltage of the switches X2 and X4 is less than Vcc−Vmin, then the switch X2 and/or the switch X4 will provide low resistance and conduct current. This will pull the voltage on the output line 106-0 to Vmin+Vdrop. Thus, the margin on the output line 106-0 is Vcc−(Vmin +Vdrop). The switch pairs 110-1 through 110-3 operate similarly with respect to the switch pair 110-0. The switch pairs 110-0 through 110-3 represent a second stage 116 of the decoder circuit 100 to receive the input signals A0 and A1 and logical inversions of the input signals A0 and A1.

The decoder circuit 100 has been described as having two input signals and four output signals. In general, a decoder circuit having N inputs and 2^{N} outputs can be formed based on the decoder circuit 100. Also, the decoder circuit 100 includes a configuration of bias logic and threshold switches to form inverters and AND gates. It is to be understood that the bias logic and threshold switches can be implemented as different logical functions, such as OR, NAND, NOR, XOR, and the like, in order to perform the overall function of decoding the input to produce the output as desired.

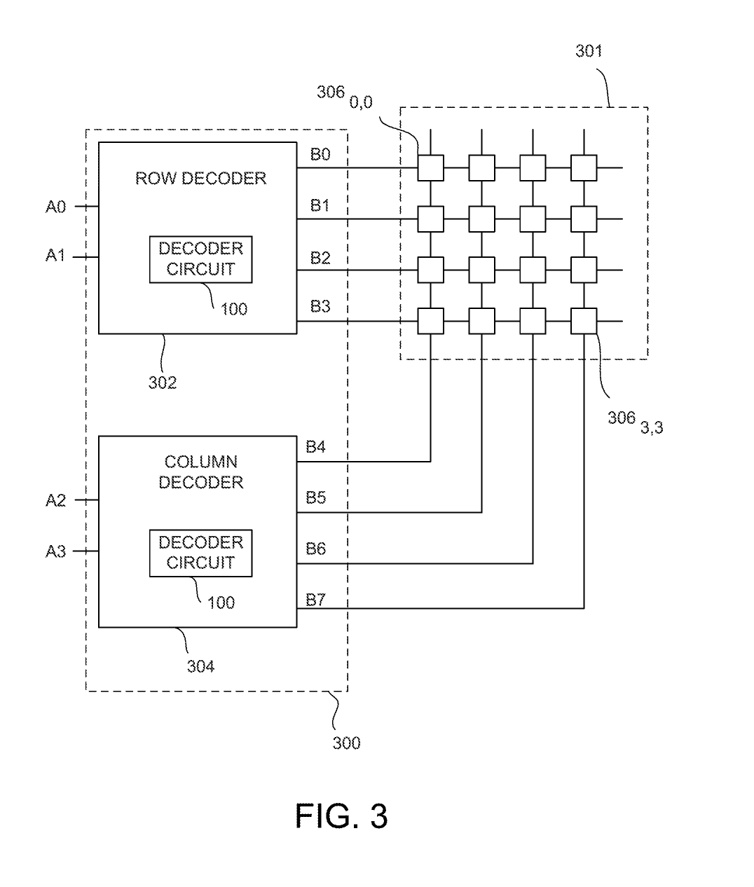

FIG. 3 is a block diagram showing a memory controller circuit 300 according to an example implementation. The memory controller circuit 300 can be coupled to a memory 301. The memory 301 can include a matrix of memory cells 306_{0,0} through 306_{3,3}. A memory cell 306_{x,y} represents a memory cell at row X and column Y. The memory controller circuit 300 includes a row decoder 302 and a column decoder 304. The row decoder 302 includes a 2-bit input (A1 A0) and a four-bit output (B3B2B1 B0). The four-bit output (B3B2B1 B0) of the row decoder 302 is respectively coupled to the rows 0 through 3 of the memory. The column decoder 304 includes a 2-bit input (A3A2) and a four bit output (B7B6B5B4). The four-bit output (B7B6B5B4) of the column decoder 304 is respectively coupled to columns 0 through 3 of the memory. Each of the row decoder 302 and 304 can include a decoder circuit 100 as constructed and described above with respect to FIG. 1. The symbol A3A2A1A0 provided by the respective input signals provide an address for the memory 301. The address A3A2A1A0 selects one of the memory cells 306. The symbol A1A0 selects the row, and the symbol A3A2 selects the column.

The memory controller circuit 300 can use resistances and MIM switches to form the decoder circuits. The MIM threshold switch-based memory controller provides manageable voltage margins and is substrate agnostic. In examples, the MIM threshold switch-based decoder devices can be formed using thin-film processes. The current-controlled negative resistance characteristic of the MIM devices enables reasonable margins in contrast to resistor/diode-based devices. For purposes of clarity by example, a 4×4 array of memory cells has been shown. It is to be understood that a memory controller circuit using MIM threshold switch-based decoder circuits can be devised to address a memory of any size.

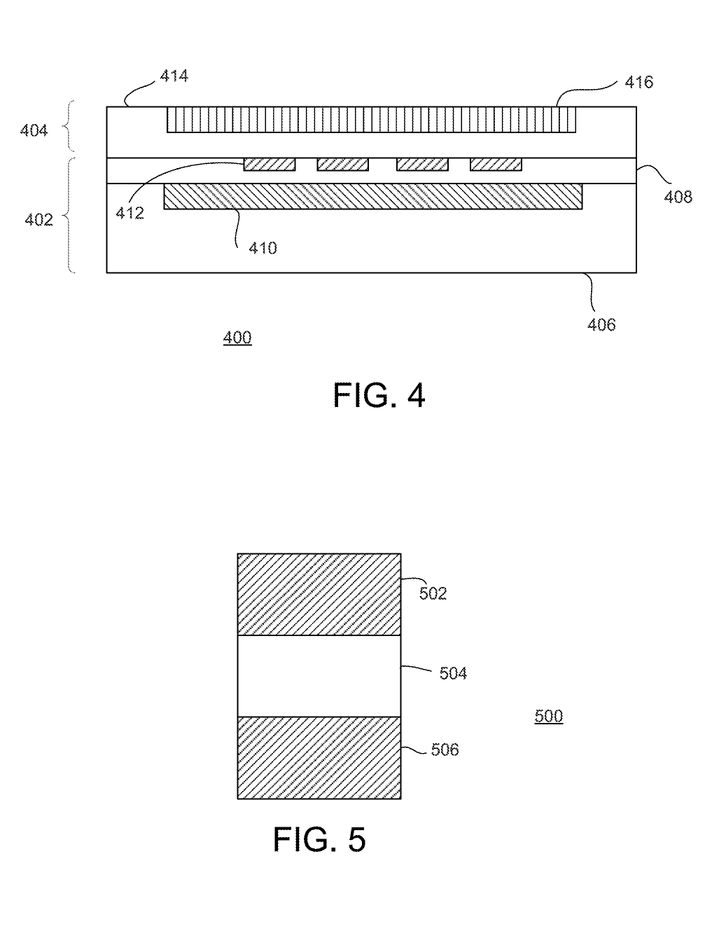

FIG. 4 is a diagram showing an IC device 400 according to an example implementation. The IC device 400 includes an IC die 402 and a thin-film device 404. The IC die 402 can include a semiconductor substrate 406 and conductive interconnect 408. Active components 410 can be formed in the semiconductor substrate 406 using various semiconductor fabrication processes, such as complementary metal oxide semiconductor (CMOS) processes. The conductive interconnect 408 is formed on the semiconductor substrate 406 and can include a plurality of conductive layers patterned to make various electrical connections between the active components 410. Together, the conductive interconnect 408 and the active components 410 form at least one circuit, such as a memory or any other type of circuit.

The thin-film device 404 includes thin-film layers deposited to form decoder circuitry 416. The decoder circuitry 416 can be formed on the IC die 402 by depositing thin-films to form various components. The thin-films can be deposited on top of a layer of the conductive interconnect 408 and be electrically connected thereto. In an example, the decoder circuitry 416 includes conductors, resistors, and MIM devices arranged to form decoder circuit(s) such as the decoder circuit 100 of FIG. 1 or similar such decoder circuits. The decoder circuitry 416 can be electrically coupled to portions 412 of the conductive interconnect 408 such that the decoder circuitry 416 can receive input signals from, and provide output signals to, circuits formed on the IC die 402. For example, the semiconductor device 400 can be a three-dimensional (3D) memory device, where the IC die 402 is a memory IC and the thin-film device 404 includes a memory controller for controlling the memory IC. Moving the controller off of the IC die 402 frees area on the substrate 406 for other circuits or for a larger memory array.

While 3D memory device is described by way of example, the IC device 400 can be used for various other applications requiring decoder circuits. The MIM threshold switch devices of the decoder circuits can be form on various substrates other than silicon-based substrates and are thus “substrate agnostic”. While the IC die 402 has been described as a silicon-based device (e.g., CMOS), it is to be understood that the thin-film device 404 can be formed on any type of IC die 402, including non-silicon-based devices.

FIG. 5 shows a cross-section of an MIM threshold switch 500 according to an example implementation. The MIM threshold switch includes an electrode 502, an electrode 506, and an oxide 504 between the electrodes 502 and 506. The oxide 504 can be made from various materials, including vanadium oxide materials, iron oxide materials, niobium oxide materials, titanium oxide materials, manganese oxide materials, and the like. The electrodes 502 and 506 can be mode from various conductive materials, such as copper, gold, aluminum, platinum, and the like. The metal-oxide-metal structure of the MIM threshold switch 500 can exhibit negative resistance with the application of a current to the metal-oxide-metal device. Negative resistance occurs when electric current is injected between the electrodes 502 and 506, which locally heats the oxide 504 above a transition temperature. The transition temperature is the temperature at which a solid material changes from one crystal state to another. This rise above the transition temperature causes current filamentation to occur. Current filamentation is an inhomogeneity in the current density distribution orthogonal to the direction of current flow. This current filamentation is what causes the negative resistance at certain current levels. The MIM threshold switch 500 can be formed on a thin-film IC using a first metal film for the electrode 502, an insulating film (oxide film) for the oxide 504, and a second metal film for the electrode 506.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A decoder circuit, comprising:
a plurality of input lines to receive select signals;
a bias logic to provide a voltage bias;
a plurality of output lines to provide output signals;
a plurality of metal-insulator-metal (MIM) threshold switches coupled to the plurality of input lines, the bias logic, and the plurality of output lines, each of the plurality of MIM threshold switches operating as either a current-controlled positive or negative resistance to map an input logic state of the select signals to an output logic state of the output signals.

2. The decoder circuit of claim 1, wherein the plurality of MIM threshold switches comprise:
a first stage having a first plurality of MIM threshold switches coupled to the bias logic and the plurality of input lines to provide logically inverted select signals with respect to the select signals; and
a second stage having a second plurality of MIM threshold switches, the second plurality of MIM threshold switches coupled to the bias logic in parallel to the first stage, and coupled to the plurality of input lines, the plurality of output lines and the first stage to receive the inverted select signals.

3. The decoder circuit of claim 2, wherein the second plurality of MIM threshold switches logically provide a plurality of AND gates coupled to the bias logic in parallel to each other, the plurality of AND gates each having inputs receiving the select signals and the logically inverted select signals and outputs respectively coupled to the plurality of output lines to provide the output signals.

4. The decoder circuit of claim 2, wherein the first plurality of MIM threshold switches logically provide a plurality of inverter gates coupled to the bias logic in parallel to each other, the plurality of inverter gates each having an input receiving one of the select signals and an output providing one of the logically inverted select signals.

5. The decoder circuit of claim 1, wherein the bias logic comprises a plurality of resistances.

6. A memory controller circuit, comprising:
a first decoder circuit to provide row selection signals; and
a second decoder circuit to provide column selection signals;
wherein each of the first decoder circuit and the second decoder circuit includes:
a plurality of input lines to receive select signals;
a bias logic to provide a voltage bias;
a plurality of output lines to provide output signals;
a plurality of metal-insulator-metal (MIM) threshold switches coupled to the plurality of input lines, the bias logic, and the plurality of output lines, each of the plurality of MIM threshold switches operating as either a current-controlled positive or negative resistance to map an input logic state of the select signals to an output logic state of the output signals.

7. The memory controller circuit of claim 6, wherein the plurality of MIM threshold switches in each of the first and second decoder circuits comprises:
a first stage having a first plurality of MIM threshold switches coupled to the bias logic and the plurality of input lines to provide logically inverted select signals with respect to the select signals; and
a second stage having a second plurality of MIM threshold switches, the second plurality of MIM threshold switches coupled to the bias logic in parallel to the first stage, and coupled to the plurality of input lines, the plurality of output lines and the first stage to receive the inverted select signals.

8. The memory controller circuit of claim 6, wherein the bias logic in each of the first and second decoder circuits comprises a plurality of resistances.

9. The memory controller circuit of claim 6, wherein the first and second decoder circuits are formed in a thin-film integrated circuit (IC).

10. The memory controller circuit of claim 9, wherein each of the plurality of MIM threshold switches is formed on the thin-film IC using a first metal film, an insulating film, and a second metal film.

11. An integrated circuit (IC) device, comprising:
an IC die having conductive interconnect formed on a substrate; and
a thin-film device formed on the IC die and electrically coupled to the conductive interconnect, the thin-film device having a decoder circuit including:
a plurality of input lines to receive select signals;
a bias logic to provide a voltage bias;
a plurality of output lines to provide output signals;
a plurality of metal-insulator-metal (MIM) threshold switches coupled to the plurality of input lines, the bias logic, and the plurality of output lines, each of the plurality of MIM threshold switches operating as either a current-controlled positive or negative resistance to map an input logic state of the select signals to an output logic state of the output signals.

12. The IC device of claim 11, wherein the thin-film device comprises a plurality of thin film layers formed over a layer of the conductive interconnect.

13. The IC device of claim 11, wherein each of the plurality of MIM threshold switches is formed on the thin-film device using a first metal film, an insulating film, and a second metal film.

14. The IC device of claim 11, wherein the plurality of MIM threshold switches comprise:
a first stage having a first plurality of MIM threshold switches coupled to the bias logic and the plurality of input lines to provide logically inverted select signals with respect to the select signals; and
a second stage having a second plurality of MIM threshold switches, the second plurality of MIM threshold switches coupled to the bias logic in parallel to the first stage, and coupled to the plurality of input lines, the plurality of output lines and the first stage to receive the inverted select signals.

15. The IC device of claim 11, wherein the bias logic comprises a plurality of resistances.
